(19) United States
(12) Patent Application Publication
(10) Pub. No.: US 2020/0021242 A1
(43) Pub. Date: Jan. 16, 2020

(54) OVEN CONTROLLED CRYSTAL OSCILLATOR DEVICE, AND FREQUENCY COMPENSATION METHOD THEREFOR

(71) Applicant: GUANGDONG DAPU TELECOM TECHNOLOGY CO., LTD., Dongguan City (CN)

(72) Inventors: Yifeng Wang, Dongguan City (CN); Chaosheng Liu, Dongguan City (CN); Wencai Qiu, Dongguan City (CN)

(73) Assignee: GUANGDONG DAPU TELECOM TECHNOLOGY CO., LTD., Dongguan City (CN)

(21) Appl. No.: 16/471,087

(22) PCT Filed: Feb. 24, 2017
(86) PCT No.: PCT/CN2017/074837

§ 371 Date: Jun. 19, 2019

(30) Foreign Application Priority Data
Dec. 19, 2016 (CN) 201611179491.6

(51) Int. Cl. H03B 5/04; H03L 1/02

(52) U.S. Cl. CPC H03B 5/04; H03B 2201/0291; H03L 1/022

(57) ABSTRACT

Disclosed are an oven controlled crystal oscillator device and a frequency compensation method thereof. The oven controlled crystal oscillator device includes: an oven, a microcontroller, an oven controlled crystal oscillator disposed in the oven, and a current detection circuit. The current detection circuit is coupled to the oven controlled crystal oscillator, and is configured to obtain an operating current value of the oven controlled crystal oscillator and provide the operating current value to the microcontroller. The microcontroller is configured to determine a frequency compensation amount according to the operating current value based on a frequency compensation rule, and output the frequency compensation amount to the oven controlled crystal oscillator to compensate an output frequency.

### TECHNICAL FIELD

The present disclosure relates to the technical field of crystal oscillators, for example, to an oven controlled crystal oscillator and a frequency compensation method therefor.

### BACKGROUND

“Frequency-temperature stability” is one of important technical indicators of an oven controlled crystal oscillator (OCXO). After the oven controlled crystal oscillator is designed, the “frequency-temperature stability” indicator many times still cannot meet the application requirements. It is a long-term goal of crystal oscillator manufacturers and user applications to continue to improve this indicator. Therefore, temperature compensation technique has been introduced to improve the temperature stability of OCXO.

A related temperature compensation solution is shown in FIG. 1, which is a schematic diagram of an oven controlled crystal oscillator system in the related art. The oscillator system includes a housing 10, a temperature sensor 11 disposed in the housing 10, a microcontroller (MCU) 12, a digital to analog converter (DAC) 13, an oven 14, and an OCXO 15 disposed in the oven 14. The temperature sensor 11 is disposed in the housing 10 and is used for reading an environmental temperature in the housing 10 and transmitting the environmental temperature to the MCU 12. At different temperatures of the oven, the MCU 12 would transmit different frequency compensation amounts to the DAC 13. After the frequency compensation amounts are converted from a digital signal to an analog signal by the DAC 13, the analog signal is transmitted to an analog voltage control end (VC) of the OCXO 15 to adjust an output frequency of a frequency output end (Fout) of the OCXO 15 is adjusted for compensation.

However, as requirements on the technical indicators are constantly rising, the compensation solution has come to a bottleneck. The reason is as follows. Because the temperature sensor is disposed between the oven and the housing and a temperature setpoint of the oven needs to be higher than a working environmental temperature; for example, when the OCXO needs to work at an environmental temperature range of −40° C. ˜85° C., the temperature of the oven may be set above 90° C. When the OCXO works at −40° C. or 85° C., a difference of temperature gradients among the housing, the temperature sensor, and the oven is different. When the OCXO works at −40° C. or 85° C., the difference of the temperature gradients among the housing, the temperature sensor and the oven changes when the airflow of the external environment changes. Thus, when the OCXO works at the same temperature and the airflow is different, the temperature gradient of the temperature sensor will change, and the frequency compensation amount given by the MCU will change slightly. Although this slight change may be ignored when the requirement of the technical indicator of the frequency temperature stability of the OCXO is low, when the technical indicator of the frequency temperature stability of the OCXO needs to be lower than the slight changing amount, this compensation method would not be able to meet the application requirements.

### SUMMARY

The present disclosure provides an oven controlled crystal oscillator and a frequency compensation method thereof, which may achieve a high precision compensation for the frequency of an oven controlled crystal oscillator.

Embodiments of the present disclosure provide an oven controlled crystal oscillator device, which includes an oven, a microcontroller, an oven controlled crystal oscillator disposed in the oven, and a current detection circuit.

The current detection circuit is coupled to the oven controlled crystal oscillator, and is configured to obtain an operating current value of the oven controlled crystal oscillator and provide the operating current value to the microcontroller; and the microcontroller is configured to determine a frequency compensation amount according to the operating current value based on a frequency compensation rule, and output the frequency compensation amount to the oven controlled crystal oscillator to compensate an output frequency.

Optionally, the device further includes an analog-to-digital converter that is coupled to the microcontroller and to the oven controlled crystal oscillator, and that is configured to convert the frequency compensation amount into an analog electrical signal and output the analog electrical signal to an analog voltage control end of the oven controlled crystal oscillator to allow the analog voltage control end to adjust the output frequency according to the analog electrical signal.

Optionally, the device further includes a housing, where the oven, the oven controlled crystal oscillator, the microcontroller, the current detection circuit and the analog-to-digital converter are all disposed in the housing. As an alternative, the oven and the oven controlled crystal oscillator are disposed outside the housing, while the microcontroller, the current detection circuit, and the analog-to-digital converter are disposed inside the housing. As another alternative, the housing comprises a first housing and a second housing, where the current detection circuit, the oven, and the oven controlled crystal oscillator are disposed in the first housing, while the microcontroller and the analog-to-digital converter are disposed in the second housing.

Embodiments of the present disclosure further provide an equipment having an oven controlled crystal oscillator, which includes any of the above-described oven controlled crystal oscillator device.

Embodiments of the present disclosure further provide a frequency compensation method of an oven controlled crystal oscillator device, the frequency compensation method being performed by any of the above-described oven controlled crystal oscillator device. The frequency compensation method includes: obtaining, by the current detection circuit, an operating current value of the oven controlled crystal oscillator, and providing the operating current value to a microcontroller; determining, by the microcontroller, a frequency compensation amount according to the operating current value based on a frequency compensation rule; and outputting, by the microcontroller, the frequency compensation amount to the oven controlled crystal oscillator to compensate an output frequency.

Optionally, in the above frequency compensation method, outputting by the microcontroller the frequency compensation amount to the oven controlled crystal oscillator to compensate the output frequency includes: outputting, by the microcontroller, the frequency compensation amount to an analog-to-digital converter; and converting, by the analog-to-digital converter, the frequency compensation amount into an analog electrical signal, and outputting the analog electrical signal to an analog voltage control end of the oven controlled crystal oscillator to allow the analog voltage control end to adjust the output frequency according to the analog electrical signal.

Optionally, the frequency compensation method further includes: obtaining operating current values and frequency drifts of the oven controlled crystal oscillator under different temperature values of the oven; and establishing the frequency compensation rule according to correspondences between the temperature values, the operating current values, and the frequency drifts, and storing the in the microcontroller.

Optionally, in the above frequency compensation method, determining by the microcontroller the frequency compensation amount according to the operating current value based on the frequency compensation rule includes: obtaining, by the microcontroller the frequency compensation rule corresponding to the operating current value; and obtaining the frequency compensation amount according to a correspondence between the operating current value and the temperature value and frequency drift in the frequency compensation rule.

Optionally, in the above frequency compensation method, the frequency drift refers to a difference between a current output frequency of the oven controlled crystal oscillator and a normal output frequency.

The present disclosure provides an oven controlled crystal oscillator device and a frequency compensation method thereof. By obtaining an operating current value of an oven controlled crystal oscillator, a frequency compensation amount can be determined, thereby avoiding the influence of temperature gradient on frequency compensation and improving the precision of frequency compensation.

### BRIEF DESCRIPTION OF DRAWINGS

To illustrate the technical solutions found in embodiments of the present disclosure or in the related art, drawings to be used in a description of the embodiments or the related art will be briefly described below.

FIG. 1 is a schematic diagram illustrating an oven controlled crystal oscillator system in the related art;

FIG. 2 is a first schematic diagram illustrating an oven controlled crystal oscillator device according to Embodiment one of the present disclosure;

FIG. 3 is a second schematic diagram illustrating an oven controlled crystal oscillator device according to Embodiment one of the present disclosure;

FIG. 4 is a third schematic diagram illustrating an oven controlled crystal oscillator device according to Embodiment one of the present disclosure; and

FIG. 5 is a flowchart illustrating a frequency compensation method for an oven controlled crystal oscillator device according to Embodiment three of the present disclosure.

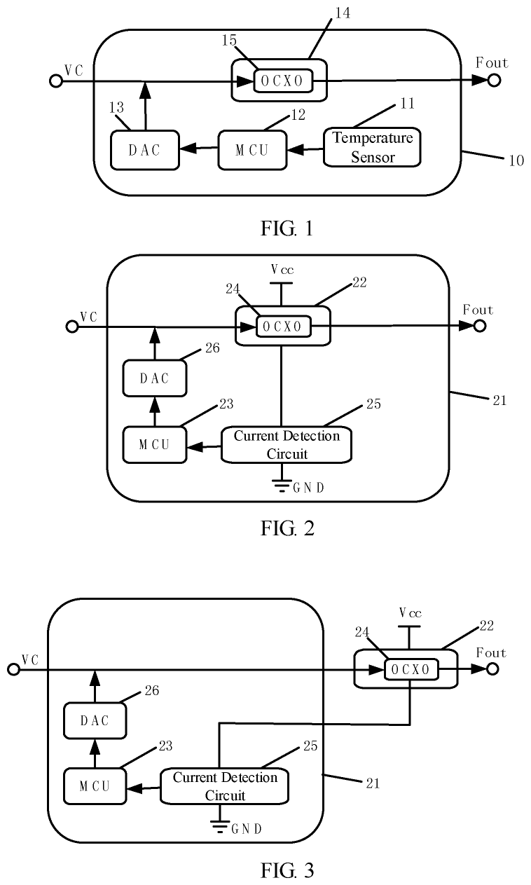

### DETAILED DESCRIPTION

Hereinafter the present disclosure will be described in detail in conjunction with the drawings and embodiments. The detailed description of the embodiments set forth below is intended to explain and not to limit the present disclosure. For ease of description, only part rather than all of structures related to the present disclosure are illustrated in the drawings. In the case where no contradiction is present, the following embodiments and the features in these embodiments may be combined in an arbitrary manner.

### Embodiment One

FIG. 2 is a schematic diagram illustrating an oven controlled crystal oscillator device according to Embodiment one of the present disclosure. As illustrated in FIG. 2, the embodiment of the present disclosure provides an oven controlled crystal oscillator device. By obtaining an operating current value of the oven controlled crystal oscillator, a high precision compensation for a frequency of the oven controlled crystal oscillator may be achieved.

The oven controlled crystal oscillator device includes an oven 22, a microcontroller (MCU) 23, an oven controlled crystal oscillator (OCXO) disposed in the oven 22, and a current detection circuit 25.

The current detection circuit 25 is coupled to the OCXO 24, and is configured to obtain an operating current value of the OCXO 24, and provide the operating current value to the MCU 23.

The MCU 23 is configured to determine a frequency compensation amount according to the operating current value based on a frequency compensation rule, and output the frequency compensation amount to the OCXO 24 to compensate an output frequency.

Optionally, the device further includes a digital to analog converter (DAC) 26.

The DAC 26 is coupled to the MCU 23 and to the OCXO 24, and is configured to convert the frequency compensation amount into an analog electrical signal, and output the analog electrical signal to an analog voltage control end (VC) of the OCXO 24 to allow the analog voltage control end to adjust the output frequency according to the analog electrical signal. A frequency output end (Fout) of the OCXO 24 outputs a frequency.

Optionally, the device further includes a housing 21.

Referring to FIG. 2, the oven, the oven controlled crystal oscillator, the microcontroller, the current detection circuit, and the analog-to-digital converter are all disposed inside the housing 21.

Optionally, referring to FIG. 3, the oven and the oven controlled crystal oscillator are disposed outside the housing 21, while the microcontroller, the current detection circuit, and the analog-to-digital converter are disposed inside the housing 21.

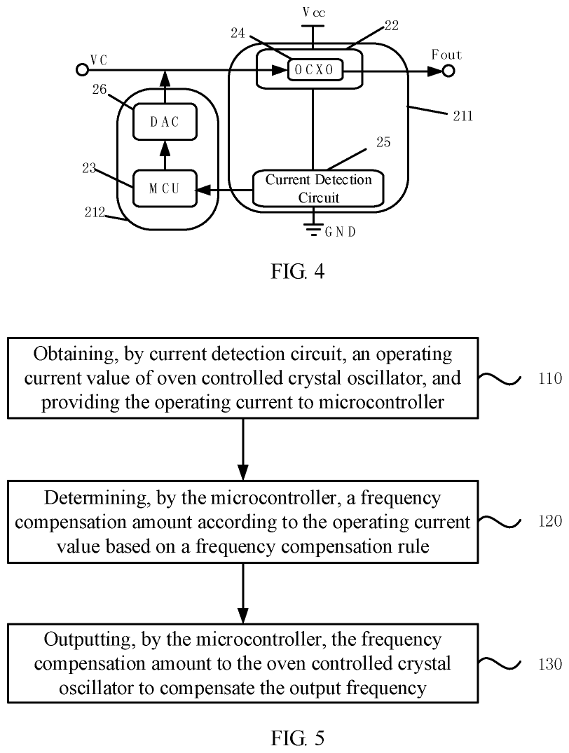

Optionally, referring to FIG. 4, the housing includes a first housing 211 and a second housing 212. The current detection circuit, the oven and the oven controlled crystal oscillator are disposed in the first housing 211, while the microcontroller and the analog-to-digital converter are disposed in the second housing 212.

In the above solution, by obtaining operating current values and frequency drifts of the crystal oscillator under different temperature values of the oven, the frequency compensation rule may be established according to correspondences between the temperature values, the operating current values, and the frequency drifts. The frequency compensation rule may be stored in the microcontroller.

Optionally, the microcontroller may obtain the frequency compensation rule according to the operating current value, and then obtain the frequency compensation amount according to the correspondence between the operating current value and the temperature value as well as frequency drift in the frequency compensation rule. The frequency compensation amount output by the analog-to-digital converter may then be converted into an analog electrical signal, and the analog-to-digital converter may output the analog electrical signal to the analog voltage control end (VC) of the oven controlled crystal oscillator, and the analog voltage control end adjusts the frequency of the oven controlled crystal oscillator.

The present disclosure provides an oven controlled crystal oscillator device. By obtaining the operating current value of the oven controlled crystal oscillator, a frequency compensation amount may be determined, thereby avoiding the influence of temperature gradient on frequency compensation and improving the precision of frequency compensation.

### Embodiment Two

Embodiment two of the present disclosure further provides an equipment having an oven controlled crystal oscillator, which includes all oven controlled crystal oscillator devices provided in Embodiment one.

Optionally, the equipment is a communications equipment.

The present disclosure provides an equipment having an oven controlled crystal oscillator. By obtaining the operating current value of the oven controlled crystal oscillator through the oven controlled oscillator device in the equipment, a frequency compensation amount may be determined, thereby avoiding the influence of temperature gradient on frequency compensation and improving the precision of frequency compensation.

### Embodiment Three

Referring to FIG. 5, FIG. 5 is a flowchart illustrating a frequency compensation method of an oven controlled crystal oscillator device according to Embodiment three of the present disclosure. This frequency compensation method is performed by the oven controlled crystal oscillator device provided by the embodiments of the present disclosure.

In step 110, the current detection circuit obtains an operating current value of the oven controlled crystal oscillator, and provides the operating current value to the microcontroller.

The operating current may be a heating operating current of the oven controlled crystal oscillator. The temperature control principle of the oven controlled crystal oscillator consists in setting the temperature in the oven above the environmental temperature by means of heating. For example, when the oven controlled crystal oscillator needs to operate at an environmental temperature of −40° C. to 85° C., then the temperature of the oven may be set above 90° C. The heating principle consists in increasing the temperature by controlling the operating current of the oven controlled crystal oscillator. With a large current, the temperature in the oven increases, while with a small current, the temperature in the oven decreases.

Optionally, the current detecting circuit may periodically obtain the operating current value of the oven controlled crystal oscillator, and periodically monitor the operating current of the oven controlled crystal oscillator for purposes of monitoring the frequency of the oven controlled crystal oscillator and timely compensating the frequency.

In step 120, the microcontroller determines a frequency compensation amount according to the operating current value based on a frequency compensation rule.

The step 120 may include the following operations. The microcontroller obtains a corresponding frequency compensation rule according to the operating current value, and obtains the frequency compensation amount according to a correspondence between the operating current value and the temperature value as well as frequency drift in the frequency compensation rule.

The frequency drift refers to a difference between a present output frequency of the oven controlled crystal oscillator and a normal output frequency. For example, the difference may equal a present output frequency value of the oven controlled crystal oscillator minus a normal output frequency value of the oven controlled crystal oscillator. If the difference is a positive number, the output frequency of the oven controlled crystal oscillator needs to be reduced; if the difference is a negative number, then the output frequency of the oven controlled crystal oscillator needs to be increased. By obtaining corresponding operating current values and frequency drifts of the crystal oscillator under different temperature values of the oven, the frequency compensation rule can be established according to the correspondence between the temperature value, the operating current value, and the frequency drift. The frequency compensation rule may be stored in the microcontroller.

When the environmental temperature changes, the temperature of the oven would be affected by the environmental temperature, causing the output frequency of the oven controlled crystal oscillator to change. When the environmental temperature changes causing the output frequency of the oven controlled crystal oscillator to change, the heating operating current of the oven controlled crystal oscillator would also change. Because heating is the core of the oven controlled crystal oscillator temperature control, and the temperature control of the oven controlled crystal oscillator is embodied in the operating current (adjusting the temperature change by controlling the operating current), the heating operating current of the oven controlled crystal oscillator will make a responsive change once the temperature of the external environment changes, where a magnitude of the heating operating current change may have the same ratio as the ratio of the temperature change of the oven controlled crystal oscillator; that is, however the external environmental temperature changes, the heating temperature control circuit of the oven controlled crystal oscillator would always make a responsive adjustment to allow the heating operating current to undergo a corresponding change. Therefore, the frequency compensation amount may be determined according to the operating current values and frequency drift amounts under different temperatures, for compensating the frequency of the oven controlled crystal oscillator.

In step 130, the microcontroller outputs the frequency compensation amount to the oven controlled crystal oscillator to compensate the output frequency.

Optionally, the step 130 may include the following operations. The microcontroller may output the frequency compensation amount to the analog-to-digital converter, which may then convert the compensation quantity to an analog electrical signal and output the analog electrical signal to an analog voltage control end of the oven controlled crystal oscillator to allow the analog voltage control end to adjust the output frequency according to the analog electrical signal.

The analog electrical signal may be an analog voltage signal. The frequency compensation amount may be determined according to the frequency drift. If an output frequency value becomes larger after the frequency drift, the output frequency may be adjusted back, otherwise, the output frequency may be increased.

Optionally, the frequency compensation method of the oven controlled crystal oscillator device further includes: obtaining corresponding operating current values and frequency drifts of the crystal oscillator under different temperature values of the oven; and establishing the frequency compensation rule according to the correspondences between the temperature values, the operating current values, and the frequency drifts, and then storing the frequency compensation rule in the microcontroller.

Assuming the oven controlled crystal oscillator has a normal output frequency of 10 Hz, a standard operating current corresponding to the normal output frequency is 5 A, and the temperature of the oven is 40° C. The oven controlled crystal oscillator is affected by the external environmental temperature so that the output frequency is changed and the present operating current value is measured as 7A. Based on the pre-established frequency compensation rule, it can be learned that the present temperature of the oven the present operating current value is 80° C., the present output frequency is 12 Hz, where the present output frequency 12 Hz minus the normal output frequency 10 Hz provides +2 Hz. That is, the frequency drift is +2 (the output frequency is increased by 2 Hz). Thus, the frequency compensation amount may be determined to be −2, and the output frequency of the oven controlled crystal oscillator may be adjusted back for compensating the output frequency by outputting the analog voltage signal corresponding to the frequency compensation amount to the analog voltage control end of the oven controlled crystal oscillator.

According to the embodiments of the present disclosure, the operating current value of the oven controlled crystal oscillator is obtained, and a frequency compensation amount is determined according to the operating current value and is output to the oven controlled crystal oscillator to compensate the output frequency. This not only reduces the influence due to the measurement error, but improves the frequency compensation accuracy.

### INDUSTRIAL APPLICABILITY

The present disclosure provides an oven controlled crystal oscillator device and a frequency compensation method of the same. An operating current value of an oven controlled crystal oscillator is obtained, and a frequency compensation amount may be determined according to the operating current value, which can avoid the influence of temperature gradient on frequency compensation and improving the precision of frequency compensation.

1. An oven controlled crystal oscillator device, comprising: an oven, a microcontroller, an oven controlled crystal oscillator disposed in the oven, and a current detection circuit, wherein
the current detection circuit is coupled to the oven controlled crystal oscillator, and is configured to obtain an operating current value of the oven controlled crystal oscillator and provide the operating current value to the microcontroller; and
the microcontroller is configured to determine a frequency compensation amount according to the operating current value based on a frequency compensation rule, and output the frequency compensation amount to the oven controlled crystal oscillator to compensate an output frequency.

2. The oven controlled crystal oscillator device of claim 1, further comprising:
an analog-to-digital converter coupled to the microcontroller and to the oven controlled crystal oscillator, the analog-to-digital converter being configured to convert the frequency compensation amount into an analog electrical signal, and output the analog electrical signal to an analog voltage control end of the oven controlled crystal oscillator to allow the analog voltage control end to adjust the output frequency according to the analog electrical signal.

3. The oven controlled crystal oscillator device of claim 2, further comprising a housing, wherein
the oven, the oven controlled crystal oscillator, the microcontroller, the current detection circuit, and the analog-to-digital converter are all disposed in the housing; or
the oven and the oven controlled crystal oscillator are disposed outside the housing, and the microcontroller, the current detection circuit, and the analog-to-digital converter are disposed inside the housing; or
the housing comprises a first housing and a second housing, wherein the current detection circuit, the oven, and the oven controlled crystal oscillator are disposed in the first housing, and the microcontroller and the analog-to-digital converter are disposed in the second housing.

4. An equipment having an oven controlled crystal oscillator, the equipment comprising an oven controlled crystal oscillator, which comprises an oven, a microcontroller, an oven controlled crystal oscillator disposed in the oven, and a current detection circuit, wherein
the current detection circuit is coupled to the oven controlled crystal oscillator, and is configured to obtain an operating current value of the oven controlled crystal oscillator and provide the operating current value to the microcontroller; and
the microcontroller is configured to determine a frequency compensation amount according to the operating current value based on a frequency compensation rule, and output the frequency compensation amount to the oven controlled crystal oscillator to compensate an output frequency.

5. A frequency compensation method of an oven controlled crystal oscillator device, the frequency compensation method being performed by an oven controlled crystal oscillator device, the oven controlled crystal oscillator device comprises an oven, a microcontroller, an oven controlled crystal oscillator disposed in the oven, and a current detection circuit, the frequency compensation method comprising:
obtaining, by the current detection circuit, an operating current value of the oven controlled crystal oscillator, and providing the operating current value to the microcontroller;
determining, by the microcontroller, a frequency compensation amount according to the operating current value based on a frequency compensation rule; and
outputting, by the microcontroller, the frequency compensation amount to the oven controlled crystal oscillator to compensate an output frequency.

6. The frequency compensation method of claim 5, wherein the oven controlled crystal oscillator device further comprises an analog-to-digital converter coupled to the microcontroller and to the oven controlled crystal oscillator, wherein outputting by the microcontroller the frequency compensation amount to the oven controlled crystal oscillator to compensate the output frequency comprises:
outputting, by the microcontroller, the frequency compensation amount to the analog-to-digital converter; and
converting, by the analog-to-digital converter, the frequency compensation amount into an analog electrical signal, and outputting the analog electrical signal to an analog voltage control end of the oven controlled crystal oscillator to allow the analog voltage control end to adjust the output frequency according to the analog electrical signal.

7. The frequency compensation method of claim 5, further comprising:
obtaining operating current values and frequency drifts of the oven controlled crystal oscillator under different temperature values of the oven; and
establishing the frequency compensation rule according to correspondences between the temperature values, the operating current values, and the frequency drifts, and storing the correspondences in the microcontroller.

8. The frequency compensation method of claim 7, wherein determining by the microcontroller the frequency compensation amount according to the operating current value based on the frequency compensation rule comprises:
obtaining, by the microcontroller, the frequency compensation rule corresponding to the operating current value according to the operating current value; and
obtaining the frequency compensation amount according to a correspondence between the operating current value and the temperature value and frequency drift in the frequency compensation rule.

9. The frequency compensation method of claim 8, wherein the frequency drift refers to a difference between a present output frequency and a normal output frequency of the oven controlled crystal oscillator.

10. The equipment of claim 4, wherein the oven controlled crystal oscillator device further comprises:
an analog-to-digital converter coupled to the microcontroller and to the oven controlled crystal oscillator, the analog-to-digital converter being configured to convert the frequency compensation amount into an analog electrical signal, and output the analog electrical signal to an analog voltage control end of the oven controlled crystal oscillator to allow the analog voltage control end to adjust the output frequency according to the analog electrical signal.

11. The equipment of claim 10, wherein the oven controlled crystal oscillator device further comprises a housing, wherein
the oven, the oven controlled crystal oscillator, the microcontroller, the current detection circuit, and the analog-to-digital converter are all disposed in the housing; or
the oven and the oven controlled crystal oscillator are disposed outside the housing, and the microcontroller, the current detection circuit, and the analog-to-digital converter are disposed inside the housing; or
the housing comprises a first housing and a second housing, wherein the current detection circuit, the oven, and the oven controlled crystal oscillator are disposed in the first housing, and the microcontroller and the analog-to-digital converter are disposed in the second housing.

12. The frequency compensation method of claim 6, wherein the oven controlled crystal oscillator device further comprises a housing, wherein
the oven, the oven controlled crystal oscillator, the microcontroller, the current detection circuit, and the analog-to-digital converter are all disposed in the housing; or
the oven and the oven controlled crystal oscillator are disposed outside the housing, and the microcontroller, the current detection circuit, and the analog-to-digital converter are disposed inside the housing; or
the housing comprises a first housing and a second housing, wherein the current detection circuit, the oven, and the oven controlled crystal oscillator are disposed in the first housing, and the microcontroller and the analog-to-digital converter are disposed in the second housing.

13. The frequency compensation method of claim 12, further comprising:
obtaining operating current values and frequency drifts of the oven controlled crystal oscillator under different temperature values of the oven; and
establishing the frequency compensation rule according to correspondences between the temperature values, the operating current values, and the frequency drifts, and storing the correspondences in the microcontroller.

14. The frequency compensation method of claim 13, wherein determining by the microcontroller the frequency compensation amount according to the operating current value based on the frequency compensation rule comprises:
obtaining, by the microcontroller, the frequency compensation rule corresponding to the operating current value according to the operating current value; and
obtaining the frequency compensation amount according to a correspondence between the operating current value and the temperature value and frequency drift in the frequency compensation rule.

15. The frequency compensation method of claim 14, wherein the frequency drift refers to a difference between a present output frequency and a normal output frequency of the oven controlled crystal oscillator.
